(19) United States
(12) Patent Application Publication
(10) Pub. No.: US 2010/0219850 A1
(43) Pub. Date: Sep. 2, 2010

(54) METHOD AND PROBE FOR THE MEASUREMENT OF PARTICLES IN A FLUID

(75) Inventor: Nils Arne Braaten, Trondheim (NO)

Correspondence Address: DENNISON, SCHULTZ & MACDONALD, 1727 KING STREET, SUITE 105, ALEXANDRIA, VA, 22314, US

(73) Assignee: ROXAR FLOW MEASUREMENT AS, Trondheim (NO)

(21) Appl. No.: 12/528,856

(22) PCT Filed: Mar. 4, 2008
(86) PCT No.: PCT/NO08/00080

§ 371 Date: Apr. 6, 2010

(30) Foreign Application Priority Data
Mar. 5, 2007 (NO) 20071215

(51) Int. Cl. G01R 27/08

(52) U.S. Cl. 324/693

(57) ABSTRACT

Method for the measurement of particles in a fluid stream by measurement of the electric resistance of a measuring element as a function of the erosion of the measuring element caused by the particles. It is advantageous to use an alloy with a—in comparison with a temperature coefficient of the resistivity (specific electric resistance) of about 1.9*10̂−3 K̂−1 (Monel® 400 or a similar alloy)—considerably lower temperature coefficient of the resistivity. It also comprises a probe (2) with such a measuring element (3).

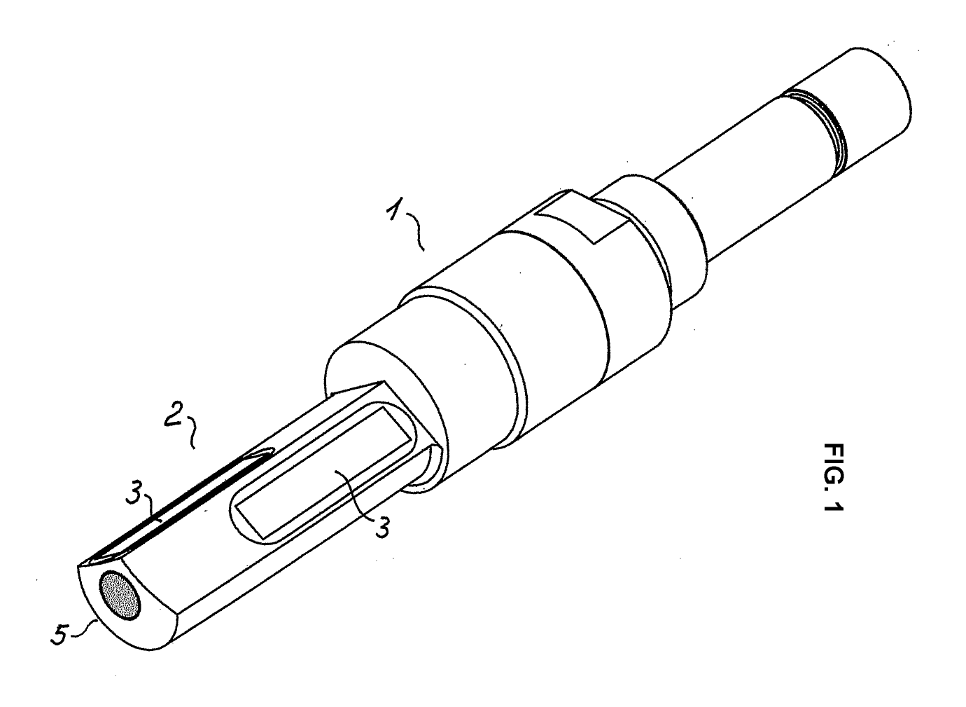

The present invention relates to a method for the measurement of particles, for example sand, in a liquid or gas stream. Further the invention relates to a probe for such use.

A method for measuring the quantity of particulate material in a fluid stream, a probe for carrying out this method and a measuring element for this probe are described in U.S. Pat. No. 5,211,677A. The method and an apparatus, including a probe with measuring elements, for carrying out this method described in this document is based on the principle that the electric resistance of a measuring element placed in an oil or gas stream containing particles will change as the measuring element is eroded by the particles. The main advantage of this method and apparatus is that it can be used for continuous monitoring of a fluid or gas stream and that it is able to provide a quantitative measurement of sand or similar particulate material present in the fluid or gas stream.

According to U.S. Pat. No. 5,211,677A the measuring element is, “in a particular embodiment” as mentioned in this document, made of an alloy known under the designation Monel® 400. It is pointed out that Monel® 400 would have advantageous properties of thermal stability, electric resistance, and wear. So the use of an alloy like Monel® 400 for a measuring element for this purpose defines the prior art concerning an alloy for the use in question.

In the practice it was proved, however, that the results of measurement being achievable with the apparatus according to U.S. Pat. No. 5,211,677A, especially with measuring elements made of Monel® 400, are not satisfactory regarding the accuracy of the measurement results.—Certainly, at the end of the description (column 6, lines 18-20) of this document, it is added that it might be “advantageous to use other materials than those particularly given in the measuring elements, for example, nickel or stainless steel.” But no particular material, especially no alloys are named, which could make it possible to get more precise results of measurement under varying conditions in the fluid or gas stream to be checked. So no clue to another special alloy than Monel® 400 for use with a measuring element in question and no indication thereon can be found in this document. In this connection it also may be of interest, that the tests with the method and apparatus according to U.S. Pat. No. 5,211,677A were done with sea water, not with oil, another fluid or gas as under conditions of practical reality.

According to the invention, the method for the measurement of particles in a fluid stream by measurement of the electric resistance of a measuring element as a function of the erosion of the measuring element caused by the mentioned particles, proposes the use of an alloy with an—in comparison with a temperature coefficient of the resistivity (specific electric resistance) of about 1.9*10̂−3 K̂−1 (Monel® 400 or a similar alloy)—considerably lower temperature coefficient of the resistivity.

Various experiments with electrical calibration of the apparatus according to U.S. Pat. No. 5,211,677A, with different materials for the probe used with this apparatus and, in particular, with other alloys for the measuring element (measuring elements) for the probe brought now the surprising result, that in the case of use of an alloy commonly known under the designation Constantan®, Isotan®, Telconstan® and other brand names very precise results of measurement could be achieved.

Constantan® as well as Isotan® and similar alloys known under various brand names are alloys with a low temperature coefficient of the resistivity (specific electric resistance) and which are, at least in the case of Constantan®, known for a long time (more than five decades) at themselves. Nevertheless these alloys did not become established in connection with the application of measuring elements for the recording of particles in a liquid or gas stream as described above, despite the fact that the measurement results achievable with the method and apparatus according to U.S. Pat. No. 5,211,677A are known as unsatisfactory over many years.

Another alloy for the purpose underlying the invention would be an alloy known under the designation Manganin®. Manganin® has a very low temperature coefficient similar to that of, for example, Constantan®. However, Manganin® does not have such a flat course of the temperature coefficient of the resistivity like Constantan®. Furthermore, Constantan® also shows better corrosion resistance than the Manganins. This property can be important dependent on the special application of such a material in connection with the measurement of particulate material in a liquid or gas stream.

After having disclosed the basic idea of the invention, it is obvious for those skilled in the art to select existing or to produce new alloys, which in a similar manner comply with the requirements identified as essential for precise measurements in connection with the recording of particles in a liquid or gas stream as described above.

Additionally to that was is mentioned hereinabove concerning the important influence of the temperature coefficient and its course over the temperature, other properties of especially Constantan® and similar alloys may have an important influence on the precision of the measurements being achievable, but it was not possible to find out details of kind and extent of these influences until now. Anyway, possibly important properties in connection with the present invention might be hardness and Izod impact strength. These properties are basically similar for Constantan® and Monel®, so in view of these properties Monel® 400 can be replaced by Constantan® without reservation.

While Monel® 400 is an alloy consisting of about 65% nickel, 33% copper and 2% iron, Constantan®, Isotan® and similar alloys are alloys consisting of about 55-57% copper, 41-45% nickel and in some cases 1% iron and/or 1% manganese. By contrast, Manganin® does not contain as much nickel as Monel®, Constantan® or Isotan®, for example.—Manganin® is an alloy consisting of about 84-86% copper, 12% manganese and 2-4% nickel. So it is clear that not a special content of nickel defines the quality of an alloy in view of electrical and mechanical properties respectively as a low temperature coefficient of the specific electric resistance (resistivity), hardness and Izod impact strength, but the whole compound of the respective alloy has to be taken into consideration for its usability for the purpose underlying the present invention.

The results of measurement which can be achieved by use of Constantan® for the measuring element are much more precise than those achievable with a measuring element made of Monel® 400. In this connection it has been found that the main reason for these substantially better results by using Constantan® instead of Monel® for the measuring element (measuring elements) is the considerably lower temperature coefficient of the resistivity of Constantan®—and thus of similar alloys—in comparison to Monel® 400.

While the temperature coefficient, of Monel® 400 is about 1.9*10̂−3 K̂−1, the temperature coefficient of Constantan® is about 0.01-0.02*10̂−3 K̂−1. So the essence of the present invention is the use of an alloy with a temperature coefficient of the resistivity which has a—in comparison with a temperature coefficient of the resistivity of about 1.9*10̂−3 K̂−1 of an alloy like Monel® 400—considerably lower temperature coefficient.

With regard to the fact, that, basically, the resistivity of alloys is in a relatively small way dependent on the temperature, the present invention forms a special selection among those alloys, resulting in very precise measurements in connection with the recording of particles in a liquid or gas stream as mentioned above.

Furthermore, Constantan®, Isotan® and similar alloys are alloys the course of the temperature coefficient of the resistivity of which is relatively flat, in other words, it is at least approximately rectilinear. This is an additional advantage of these alloys, which serves to further improve the accuracy of the measurement results.

The summary of the aforementioned advantages—very low temperature coefficient and a flat course of the temperature coefficient—of the selected alloys according to the invention are properties of a material which is ideal for a measuring element for the purpose and of the kind in question.

Additionally to the previous explanation of the present invention, the only figure of the drawing shows, in a perspective view, a probe with measuring elements for the recording of particles, for example sand, in a liquid or gas stream by measurement of the electric resistance of the measuring element as a function of the erosion of the measuring element caused by the mentioned particles as described above and usable for carrying out the method according to U.S. Pat. No. 5,211,677A with the result of much more precise measurements.

The accompanying drawing shows a probe according to one embodiment of the present invention, with two measuring elements made of a special alloy. The probe consists of a body part 1 with a measuring head 2. The probe is adapted for mounting to a wall in a conduit (not shown) for a liquid or gas stream, which in detail is shown and described in U.S. Pat. No. 511,677A, so, on this score, reference is being made to this document.—The measuring head 2 has, in the direction facing or against the liquid/gas stream, a plough-like or V-shaped configuration, while the remaining part 5 of the measuring head 2 (located in a downstream or rearmost part of the head 2) has a semicircular form. Measuring elements 3 are partially moulded into the measuring head 2 such that only an outwardly facing side of each element is exposed to the environment.

The measuring elements 3 are, according to a preferred embodiment of the present invention, made of Constantan® or a similar alloy in view of its electrical and mechanical properties as mentioned above. In other words, in case of this preferred embodiment the measuring elements consist of an alloy of about 55-57% copper and 43-45% nickel, or, as an alternative, the measuring elements consist of an alloy of about 55-57% copper, 41-45% nickel and small amounts of manganese and/or iron in the order of about 1% each. Thus, a material for the measuring elements is used, which, as the main basis for the advantage of its use, has a considerably—that means more than a power of ten—lower dependence on temperature variations than the material known for the purpose in question, that is to say. Monel® 400.

The form and arrangement of the erosion or measuring elements 3 as well as of the measuring head 2, may have embodiments different from those of the above example.

What is claimed is:

1. Method far the measurement of particles in a fluid stream by measurement of the electric resistance of a measuring element as a function of the erosion of the measuring element caused by the mentioned particles, characterized in the use of an alloy with an—in comparison with a temperature coefficient of the resistivity (specific electric resistance) of about 1.9*10⁻³ K⁻¹(Monel 400 or a similar alloy)—considerably lower temperature coefficient of the resistivity.

2. Method according to claim 1, characterised in that an alloy is used with a temperature coefficient of the resistivity, which is not greater than about 0.02*10⁻³ K⁻¹, particularly Constantan®, Manganin® or a similar alloy.

3. Method according to claim 1, characterised in that an alloy is used (Constantan®, Isotan® or a similar alloy) the course of the temperature coefficient of the resistivity of which is relatively flat, preferably substantially rectilinear.

4. Method according to claim 1, characterised in that the alloy used consists of about 55-57% copper and 43-45% nickel.

5. Method according to claim 1, characterised in that the alloy used consists of about 55-57% copper, 41-45% nickel and small amounts of manganese and/or iron in the order of about 1% each.

6. Probe (2) for the measurement of particles, for example sand, in a liquid or gas stream, with a measuring element (3), the electric resistance of which is measured as a function of the erosion of the measuring element caused by the mentioned particles, characterised in that the measuring element (3) consists of an alloy with an—in comparison with a temperature coefficient of the resistivity (specific electric resistance) of about 1.9*10⁻³ K⁻¹ (Monel® 400 or a similar alloy)—considerably lower temperature coefficient of the resistivity.

7. Probe according to claim 6, characterised in that the measuring element consists of an alloy (Constantan®, Manganin® or a similar alloy) the temperature coefficient of the resistivity of which is not greater than about 0.02*10⁻³ K⁻¹.

8. Probe according to claim 6, characterised in that the measuring element consists of an alloy (Constantan®, Isotan® or a similar alloy) the course of the temperature coefficient of the resistivity of which s relatively fiat, preferably at least approximately rectilinear.

9. Probe according to claim 6, characterised in that the measuring element consists of an alloy of about 55-57% copper and 43-45% nickel.

10. Probe according to claim 6, characterised in that the measuring element consists of an alloy of about 55-57% copper, 41-45% nickel and small amounts of manganese and/or iron in the order of about 1% each.
